(19) United States
(12) Patent Application Publication
(10) Pub. No.: US 2024/0172467 A1
(43) Pub. Date: May 23, 2024

(54) Electron Transport Layer Material and Preparation Method therefor, Electroluminescent Device and Preparation Method therefor, and Display Apparatus

(71) Applicants: Beijing BOE Technology Development Co., Ltd., Beijing (CN); BOE Technology Group Co., Ltd., Beijing (CN)

(72) Inventor: Wenhai MEI, Beijing (CN)

(21) Appl. No.: 17/778,869

(22) PCT Filed: Jun. 1, 2021
(86) PCT No.: PCT/CN2021/097751

§ 371 Date: May 23, 2022

(51) Int. Cl. H10K 50/16; H10K 71/10; H10K 85/10; H10K 102/00

(52) U.S. Cl. CPC H10K 50/16; H10K 71/10; H10K 85/111; H10K 85/1135; H10K 85/115; H10K 2102/331

(57) ABSTRACT

A material of an electron transport layer is provided in an embodiment of the present disclosure, wherein the electron transport layer material is a nanocomposite material formed of multiple carrier transport materials with different refractive indexes, and the refractive indexes of the multiple carrier transport materials increase or decrease along one direction, and refractive indexes of two adjacent carrier transport materials differ by more than 0.2.

### CROSS-REFERENCE TO RELATED APPLICATION

The present application is a U.S. National Phase Entry of International Application PCT/CN2021/097751 having an international filing date of Jun. 1, 2021, and the contents disclosed in the above-mentioned application are hereby incorporated as a part of this application.

### TECHNICAL FIELD

Embodiments of the present disclosure relates to, but are not limited to, the field of preparation of quantum dot devices, in particular to an electron transport layer material and a preparation method therefor, an electroluminescent device including the electron transport layer and a preparation method therefor, and a display apparatus including the electroluminescent device.

### BACKGROUND

A Quantum Dots Light Emitting Diode Display (QLED Display) is a new display technology based on an organic light emitting display. A light-emitting layer in a QLED is a quantum dot layer. Its principle is that electrons/holes are injected into the quantum dot layer through an electron/hole transport layer, and the electrons and the holes are combined in the quantum dot layer to emit light. Compared with an Organic Light Emitting Diode Display (OLED Display), the QLED has advantages such as narrow luminous peak, high color saturation, and wide color gamut. Some quantum dot LED displays have a problem of a low luminous efficiency.

### SUMMARY

The following is a summary of subject matters described herein in detail. This summary is not intended to limit the scope of protection of claims.

An embodiment of the present disclosure provides an electron transport layer material, wherein the electron transport layer material is a nanocomposite material formed of multiple carrier transport materials with different refractive indexes, and the refractive indexes of the multiple carrier transport materials increase or decrease along one direction, and refractive indexes of two adjacent carrier transport materials differ by more than 0.2.

An embodiment of the present disclosure further provides a method for preparing the electron transport layer material as described above, wherein the electron transport layer material is an inorganic-inorganic nanocomposite material formed of multiple inorganic electron transport materials, the preparation method includes: (1) providing a first inorganic electron transport material and a second inorganic electron transport material having different refractive indexes, wherein a refractive index of the first inorganic electron transport material is greater than a refractive index of the second inorganic electron transport material by more than 0.2; (2) depositing a seed crystal of the first inorganic electron transport material on a base material, and growing a nanomaterial of the first inorganic electron transport material on the seed crystal by using an in-situ growth method; (3) contacting a solution of the second inorganic electron transport material with one end of the nanomaterial of the first inorganic electron transport material obtained in the step (2) and performing ion exchange to obtain an inorganic-inorganic nanocomposite material formed of the first inorganic electron transport material and the second inorganic electron transport material, wherein the inorganic-inorganic nanocomposite material is the electron transport layer material.

An embodiment of the present disclosure further provides a method for preparing the electron transport layer material as described above, wherein the electron transport layer material is an inorganic-organic nanocomposite material formed of an inorganic electron transport material and an organic carrier transport material, the preparation method includes: (1) providing an inorganic electron transport material; (2) synthesizing a nanomaterial of the inorganic electron transport material containing an organic ligand; (3) wrapping asymmetrically the nanomaterial of the inorganic electron transport material obtained in the step (2) with a wrapping material to expose one end of the nanomaterial of the inorganic electron transport material; (4) performing a grafting reaction between the organic ligand at the exposed end of the nanomaterial of the inorganic electron transport material obtained in the step (3) and an organic grafting material, thereby introducing the organic carrier transport material into the exposed end of the nanomaterial of the inorganic electron transport material, and removing the wrapping material to obtain an inorganic-organic nanocomposite material, wherein the inorganic-organic nanocomposite material is the electron transport layer material.

An embodiment of the present disclosure further provides an electroluminescent device, including an anode, a cathode, a light-emitting layer disposed between the anode and the cathode, and an electron transport layer disposed between the light-emitting layer and the cathode, wherein the electron transport layer includes the electron transport layer material described in any one of the foregoing embodiments.

An embodiment of the present disclosure further provides a method for preparing the electroluminescent device as described above, wherein an electron transport layer material of an electron transport layer of the electroluminescent device is an inorganic-inorganic nanocomposite material formed of multiple inorganic electron transport materials, the preparation method includes: preparing an anode on a substrate; preparing a light-emitting layer on a side of the anode away from the substrate; and preparing the electron transport layer on a side of the light-emitting layer away from the anode; and a preparation process of the electron transport layer includes: (1) providing a first inorganic electron transport material and a second inorganic electron transport material having different refractive indexes, wherein a refractive index of the first inorganic electron transport material is greater than a refractive index of the second inorganic electron transport material by more than 0.2; (2) depositing a seed crystal of the first inorganic electron transport material on the light-emitting layer, and growing a nanomaterial of the first inorganic electron transport material on the seed crystal by using an in-situ growth method; (3) contacting a solution of the second inorganic electron transport material with one end of the nanomaterial of the first inorganic electron transport material obtained in the step (2) and performing ion exchange to obtain an inorganic-inorganic nanocomposite material formed of the first inorganic electron transport material and the second inorganic electron transport material, wherein a plurality of the inorganic-inorganic nanocomposite materials form the electron transport layer on the light-emitting layer.

An embodiment of the present disclosure further provides a method for preparing the electroluminescent device as described above, wherein an electron transport layer material of an electron transport layer of the electroluminescent device is an inorganic-organic nanocomposite material formed of an inorganic electron transport material and an organic carrier transport material, the preparation method includes: preparing an anode on a substrate; preparing a light-emitting layer on a side of the anode away from the substrate; and preparing the electron transport layer on a side of the light-emitting layer away from the anode; and a preparation process of the electron transport layer includes: (1) providing an inorganic electron transport material; (2) synthesizing a nanomaterial of the inorganic electron transport material containing an organic ligand; (3) wrapping asymmetrically the nanomaterial of the inorganic electron transport material obtained in the step (2) with a wrapping material to expose one end of the nanomaterial of the inorganic electron transport material; (4) performing a grafting reaction between the organic ligand at the exposed end of the nanomaterial of the inorganic electron transport material obtained in the step (3) with an organic grafting material, thereby introducing an organic carrier transport material into the exposed end of the nanomaterial of the inorganic electron transport material, and removing the wrapping material to obtain an inorganic-organic nanocomposite material; (5) dissolving the inorganic-organic nanocomposite material prepared in the step (4) in a solvent, placing it over the light-emitting layer of the electroluminescent device, and forming the electron transport layer on the light-emitting layer under a baking condition; wherein one end of the electron transport layer material close to the light-emitting layer has same hydrophilicity and hydrophobicity as the light-emitting layer, hydrophilicity and hydrophobicity of one end of the electron transport layer material away from the light-emitting layer is opposite to hydrophilicity and hydrophobicity of the light-emitting layer, and repulsion of hydrophilicity and hydrophobicity enables the electron transport layer material to be erect to achieve a vertical arrangement with respect to the light-emitting layer.

An embodiment of the present disclosure further provides a display apparatus, including multiple electroluminescent devices described in any one of the foregoing embodiments.

Other aspects will become apparent upon reading and understanding of the drawings and detailed description.

### BRIEF DESCRIPTION OF DRAWINGS

Accompanying drawings are used for providing further understanding of technical solutions of the present disclosure, constitute a part of the specification, and are used for explaining the technical solutions of the present disclosure together with the embodiments of the present disclosure, and do not constitute limitations on the technical solutions of the present disclosure. Shapes and sizes of components in the accompanying drawings do not reflect actual scales, and are only intended to schematically illustrate contents of the present disclosure.

FIG. 1 is a schematic diagram of a structure of an upright QLED device according to an embodiment of the present disclosure.

FIG. 2 is a schematic diagram of a preparation process of a QLED device according to Embodiment one of the present disclosure.

FIG. 3 is a schematic diagram of a preparation process of a QLED device according to Embodiment two of the present disclosure.

FIG. 4 is a schematic diagram of a chemical reaction of asymmetric modification for a nanorod in the Embodiment two of the present disclosure.

Meanings of symbols in the accompanying drawings are as follows.
1—Zinc oxide seed crystal; 2—Zinc oxide nanorods; 2′—Zinc oxide; 2″—Zinc oxide powder; 3—Magnesium oxide; 4—Ethanolamine ligand; 5—Continuous phase; 6—Dispersed phase; 7—Polymer.
100—Substrate with a first Indium Tin Oxide (ITO) layer deposited; 200—Ag layer; 300—Second ITO layer; 400—Hole injection layer; 500—Hole transport layer; 600—Quantum dot layer; 700—Electron transport layer; 800—Cathode; 1000—Front film layer.

### DETAILED DESCRIPTION

Those of ordinary skills in the art should understand that modifications or equivalent substitutions may be made to the technical solutions of the present disclosure without departing from the spirit and scope of the technical solutions of the present disclosure, and should all fall within the scope of the claims of the present disclosure.

In the accompanying drawings, a size of a constituent element, a thickness of a layer, or a region is sometimes exaggerated for clarity. Therefore, the embodiments of the present disclosure are not necessarily limited to the size, and shapes and sizes of various components in the drawings do not reflect actual scales. In addition, the accompanying drawings schematically illustrate some examples, and the embodiments of the present disclosure are not limited to shapes or numerical values shown in the accompanying drawings.

In the description herein, “parallel” refers to a state in which an angle formed by two straight lines is above −10 degrees and below 10 degrees, and thus also includes a state in which the angle is above −5 degrees and below 5 degrees. In addition, “perpendicular” refers to a state in which an angle formed by two straight lines is above 80° and below 100°, and thus also includes a state in which the angle is above 85° and below 95°.

In top emission QLED devices of some technologies, in order to improve a light extraction efficiency, methods adopted include device surface roughening, adopting film layers with different refractive indexes for a device structure, and so on. By adopting a structure of film layers with different refractive indexes, light passes through film layers whose refractive indexes gradually decrease in sequence from a light-emitting layer, which may increase refraction of light and a final luminous efficiency. However, in order to achieve this purpose, multiple processes are required for prepare a structure of multiple film layers, which will increase interface defects, and degrade device performance. In addition, a microcavity effect needs to be considered for a top emission device generally, so in order to achieve a higher light extraction efficiency, a film thickness of each layer must be accurately controlled, while at the same time, the film thickness of each layer cannot be varied in a certain range, which limits improvement of electrical performance of the device.

An embodiment of the present disclosure provides an electron transport layer material, wherein, the electron transport layer material is a nanocomposite material formed of multiple carrier transport materials with different refractive indexes, wherein the refractive indexes of the multiple carrier transport materials increase or decrease along one direction, and refractive indexes of two adjacent carrier transport materials differ by more than 0.2.

For the electron transport layer material of the embodiment of the present disclosure, the nanocomposite material formed of the multiple carrier transport materials with different refractive indexes is adopted, the refractive indexes of the multiple carrier transport materials increase or decrease along one direction, and refractive indexes of two adjacent carrier transport materials differ by more than 0.2. Thus, in a case that the electron transport layer material of the embodiment of the present disclosure is applied to a top emission electroluminescent device (such as a QLED) including an electron transport layer, changes of refractive index of light from a high refractive index to a low refractive index may be achieved by the electron transport layer, thereby improving a refractive effect of light, and improving a light extraction efficiency.

In some exemplary embodiments, the electron transport layer material may be an inorganic-inorganic nanocomposite material formed of multiple inorganic electron transport materials, or an inorganic-organic nanocomposite material formed of an inorganic electron transport material and an organic carrier transport material.

In some exemplary embodiments, the inorganic electron transport material may be formed of a non-metal element and a metal element, wherein the non-metal element is selected from Group VIA or Group VIIA, and the metal element is selected from Group IIA, Group IIIA, Group IIB, Group IIIB, or Group IVB.

In some exemplary embodiments, the inorganic electron transport material may be selected from any one or more of aluminum oxide, barium fluoride, titanium dioxide, zinc sulfide, zirconium oxide, zinc selenide, magnesium oxide, zinc oxide, yttrium oxide, and aluminum fluoride.

In some exemplary embodiments, the organic carrier transport material may contain any one or more of triphenylamine unit, carbazole unit, fluorene unit, pyridine unit, and biphenyl unit.

Selections of the above inorganic electron transport materials and organic carrier transport materials may achieve energy level regulation and balance carrier transport in a QLED device.

In some exemplary embodiments, the electron transport layer material may be an inorganic-inorganic nanocomposite material formed of a first inorganic electron transport material and a second inorganic electron transport material, wherein a refractive index of the first inorganic electron transport material is larger than that of the second inorganic electron transport material, and a size ratio of the first inorganic electron transport material to the second inorganic electron transport material in a changing direction of the refractive indexes may be 4:1 to 1:4.

In an exemplary embodiment, the electron transport layer material may be an inorganic-inorganic nanocomposite material formed of zinc oxide and magnesium oxide.

In some exemplary embodiments, the electron transport layer material may be an inorganic-organic nanocomposite material formed of a third inorganic electron transport material and an organic carrier transport material, wherein a size ratio of the third inorganic electron transport material to the organic carrier transport material in a changing direction of the refractive indexes may be >10:1.

In an exemplary embodiment, the electron transport layer material may be an inorganic-organic nanocomposite material formed of zinc oxide and triphenylamine-based polymer.

In some exemplary embodiments, the nanocomposite material may be nanorod or nanoparticles, such as a nanorod.

In the embodiment of the present disclosure, when the nanocomposite material is a nanorod, the refractive indexes of the multiple carrier transport materials increase or decrease along a length direction of the nanorod, that is, a changing direction of the refractive indexes of the multiple carrier transport materials is the length direction of the nanorod.

In some exemplary embodiments, the electron transport layer material may be an inorganic-inorganic nanocomposite material formed of a first inorganic electron transport material and a second inorganic electron transport material, wherein the nanocomposite material is a nanorod, a refractive index of the first inorganic electron transport material is larger than that of the second inorganic electron transport material, and a length ratio of the first inorganic electron transport material to the second inorganic electron transport material in a changing direction of the refractive indexes may be 4:1 to 1:4.

In some exemplary embodiments, the electron transport layer material may be an inorganic-organic nanocomposite material formed of a third inorganic electron transport material and an organic carrier transport material, the nanocomposite material is a nanorod, and a length ratio of the third inorganic electron transport material and the organic carrier transport material in a direction of changes of refractive indexes may be >10:1.

In some exemplary embodiments, a length of the nanorod may be 10 nm to 100 nm.

An embodiment of the present disclosure further provides a method for preparing the electron transport layer material as described above, wherein the electron transport layer material is an inorganic-inorganic nanocomposite material formed of multiple inorganic electron transport materials, the preparation method includes follow steps.

(1) Providing a first inorganic electron transport material and a second inorganic electron transport material having different refractive indexes, wherein a refractive index of the first inorganic electron transport material is greater than that of the second inorganic electron transport material by more than 0.2.

(2) Depositing a seed crystal of the first inorganic electron transport material on a base material, and then growing a nanomaterial of the first inorganic electron transport material on the seed crystal by using an in-situ growth method.

(3) Contacting a solution of the second inorganic electron transport material with one end of the nanomaterial of the first inorganic electron transport material obtained in the step (2) and performing ion exchange on them to obtain an inorganic-inorganic nanocomposite material formed of the first inorganic electron transport material and the second inorganic electron transport material, wherein the inorganic-inorganic nanocomposite material is the electron transport layer material.

In some exemplary embodiments, the preparation method, after the step (3), may further include a following step.

(4) Continuing to perform ion exchange on one end of the nanocomposite material formed of the first inorganic electron transport material and the second inorganic electron transport material obtained in the step (3) to obtain an inorganic-inorganic nanocomposite material formed of more than three kinds of inorganic electron transport materials.

In some exemplary embodiments, time of the ion exchange in the step (3) may be 30 s to 3600 s, and a concentration of the solution of the second inorganic electron transport material may be 5 mg/ml to 50 mg/ml.

An embodiment of the present disclosure further provides a method for preparing the electron transport layer material as described above, wherein the electron transport layer material is an inorganic-organic nanocomposite material formed of an inorganic electron transport material and an organic carrier transport material, the preparation method may include following steps.

(1) Providing an inorganic electron transport material.

(2) Synthesizing a nanomaterial of the inorganic electron transport material containing an organic ligand.

(3) Wrapping asymmetrically the nanomaterial of the inorganic electron transport material obtained in the step (2) with a wrapping material to expose one end of the nanomaterial of the inorganic electron transport material.

(4) Performing a grafting reaction between the organic ligand at the exposed end of the nanomaterial of the inorganic electron transport material obtained in the step (3) and an organic grafting material, thereby introducing an organic carrier transport material into the exposed end of the nanomaterial of the inorganic electron transport material, and removing the wrapping material to obtain an inorganic-organic nanocomposite material, which is the electron transport layer material.

In some exemplary embodiments, a method used for synthesizing the nanomaterial of the inorganic electron transport material containing the organic ligand in the step (2) may be a hydrothermal method or an in-situ growth method.

An embodiment of the present disclosure further provides an electroluminescent device including an anode, a cathode, a light-emitting layer disposed between the anode and the cathode, and an electron transport layer disposed between the light-emitting layer and the cathode, wherein the electron transport layer includes the electron transport layer material as described above.

In some exemplary embodiments, the refractive indexes of the multiple carrier transport materials in the nanocomposite material vary from high to low along a direction away from the light-emitting layer.

In some exemplary embodiments, the nanocomposite material is a nanorod, wherein a length direction of the nanorod is substantially perpendicular to a plane where the light-emitting layer of the electroluminescent device is located. In this embodiment, “substantially perpendicular” may be understood as being perpendicular within a range of ±20 degrees from a vertical direction.

In some exemplary embodiments, the electron transport layer material may be an inorganic-inorganic nanocomposite material formed of a first inorganic electron transport material and a second inorganic electron transport material, wherein a refractive index of the first inorganic electron transport material is greater than that of the second inorganic electron transport material, and the first inorganic electron transport material is closer to the light-emitting layer than the second inorganic electron transport material.

In a case that LUMO (Lowest Unoccupied Molecular Orbital) energy levels of the first inorganic electron transport material and a material of the light-emitting layer are matched with each other, a size ratio of the first inorganic electron transport material to the second inorganic electron transport material in a changing direction of the refractive indexes may be 4:1. In a case that LUMO energy levels of the second inorganic electron transport material and the material of the light-emitting layer are matched with each other, the size ratio of the first inorganic electron transport material to the second inorganic electron transport material in the changing direction of the refractive indexes may be 1:4.

In some exemplary embodiments, the nanocomposite material may be a nanorod, in this case, the size ratio in the changing direction of yje refractive indexes may be a length ratio.

In some exemplary embodiments, the electroluminescent device may be a QLED device.

In some exemplary embodiments, the QLED device may have an upright structure or an inverted structure.

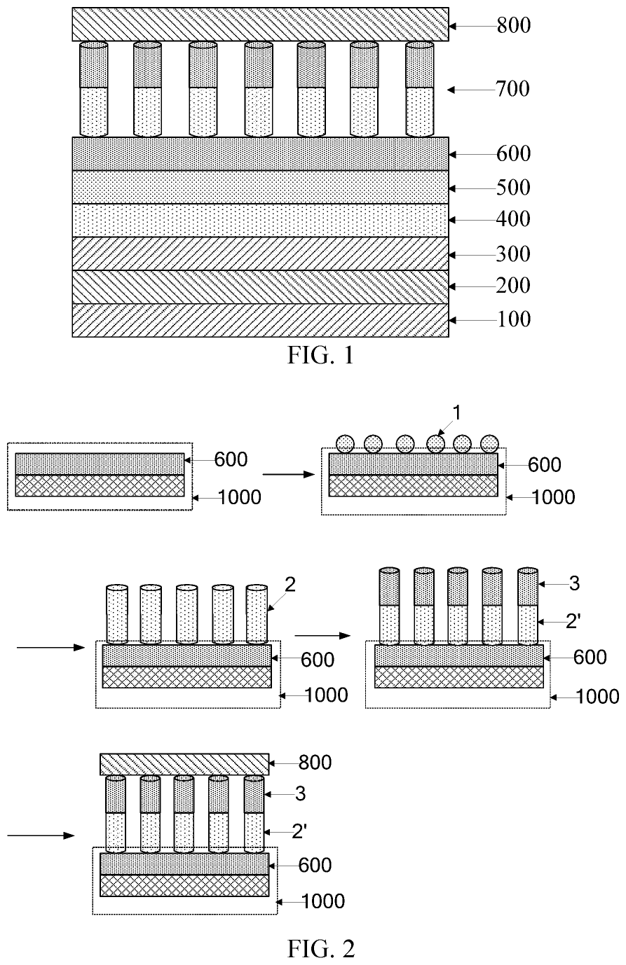

As shown in FIG. 1, FIG. 1 is a schematic diagram of a structure of an upright QLED device according to an embodiment of the present disclosure. The QLED device with an upright structure may include a substrate 100 on which a first Indium Tin Oxide (ITO) layer is deposited, an Ag layer 200, a second ITO layer 300, a hole injection layer 400, a hole transport layer 500, a quantum dot layer 600, an electron transport layer 700, and a cathode 800.

An embodiment of the present disclosure further provides a method for preparing an electroluminescent device, wherein an electron transport layer material of an electron transport layer of the electroluminescent device is an inorganic-inorganic nanocomposite material formed of multiple inorganic electron transport materials, the preparation method includes: preparing an anode on a substrate; preparing a light-emitting layer on a side of the anode facing away from the substrate; and preparing the electron transport layer on a side of the light-emitting layer away from the anode. A preparation process of the electron transport layer includes following steps.

(1) Providing a first inorganic electron transport material and a second inorganic electron transport material having different refractive indexes, wherein a refractive index of the first inorganic electron transport material is greater than that of the second inorganic electron transport material by more than 0.2.

(2) Depositing a seed crystal of the first inorganic electron transport material on the light-emitting layer, and then growing a nanomaterial of the first inorganic electron transport material on the seed crystal by using an in-situ growth method.

(3) Contacting a solution of the second inorganic electron transport material with one end of the nanomaterial of the first inorganic electron transport material obtained in the step (2) and performing ion exchange on them to obtain an inorganic-inorganic nanocomposite material formed of the first inorganic electron transport material and the second inorganic electron transport material, wherein a plurality of the inorganic-inorganic nanocomposite materials form the electron transport layer on the light-emitting layer.

According to the preparation method of the embodiment of the present disclosure, the seed crystal is provided in the step (2), the prepared nanomaterial of the first inorganic electron transport material with a highest refractive index is erect, and the ion exchange in the subsequent step (3) does not affect the erect state of the nanomaterial, so that a vertical arrangement of the electron transport layer relative to the light-emitting layer is achieved.

In some exemplary embodiments, time of the ion exchange in the step (3) may be 30 s to 3600 s, and a concentration of the solution of the second inorganic electron transport material may be 5 mg/ml to 50 mg/ml.

An embodiment of the present disclosure further provides a method for preparing an electroluminescent device, wherein an electron transport layer material of an electron transport layer of the electroluminescent device is an inorganic-organic nanocomposite material formed of an inorganic electron transport material and an organic carrier transport material. The preparation method includes: preparing an anode on a substrate; preparing a light-emitting layer on a side of the anode away from the substrate; and preparing the electron transport layer on a side of the light-emitting layer away from the anode. A preparation process of the electron transport layer includes following steps.

(1) Providing an inorganic electron transport material.

(2) Synthesizing a nanomaterial of the inorganic electron transport material containing an organic ligand.

(3) Wrapping asymmetrically the nanomaterial of the inorganic electron transport material obtained in the step (2) with a wrapping material to expose one end of the nanomaterial of the inorganic electron transport material.

(4) Performing a grafting reaction between the organic ligand at the exposed end of the nanomaterial of the inorganic electron transport material obtained in the step (3) with an organic grafting material, thereby introducing an organic carrier transport material into the exposed end of the nanomaterial of the inorganic electron transport material, and removing the wrapping material to obtain an inorganic-organic nanocomposite material.

(5) Dissolving the inorganic-organic nanocomposite material prepared in the step (4) in a solvent, placing it over the light-emitting layer of the electroluminescent device, and forming the electron transport layer on the light-emitting layer under a baking condition.

Among them, one end of the electron transport layer material close to the light-emitting layer has same hydrophilicity and hydrophobicity as those of the light-emitting layer, hydrophilicity and hydrophobicity of one end of the electron transport layer material away from the light-emitting layer is opposite to the hydrophilicity and the hydrophobicity of the light-emitting layer, and repulsion of hydrophilicity and hydrophobicity enables the electron transport layer material to be erect to achieve a vertical arrangement with respect to the light-emitting layer.

In some exemplary embodiments, one end of the electron transport layer material close to the light-emitting layer of the electroluminescent device is hydrophobic and may have a hydrophobic group, and the light-emitting layer of the electroluminescent device is hydrophilic. The electron transport layer material of the embodiment of the present disclosure may be applied to an electron transport layer of a QLED device, and the electron transport layer may include the electron transport layer material of the embodiment of the present disclosure. The QLED device may include a drive circuit layer, an anode, a light-emitting layer, an electron transport layer, and a cathode which are sequentially stacked on a base substrate. In some examples, a hole injection layer and a hole transport layer may also be provided between the anode and the light-emitting layer, and an electron injection layer may further be provided between the electron transport layer and the cathode. The QLED device may be a top emission device. When the QLED device is the top emission device, light emitted from the light-emitting layer is emitted from one side of the cathode. In the electron transport layer, refractive indexes of the multiple carrier transport materials decrease along a direction away from the light-emitting layer, so that refraction of the light may be increased and a light extraction efficiency may be improved.

An embodiment of the present disclosure also provides a display apparatus, including multiple electroluminescent devices described in any one of the foregoing embodiments. The display apparatus may be any product or component with a display function, such as a mobile phone, a tablet computer, a television, a display, a laptop computer, a digital photo frame, or a navigator.

The electron transport layer material of the embodiment of the present disclosure and its application in a QLED device are illustrated below.

### EMBODIMENT ONE

As shown in FIG. 2, FIG. 2 is a schematic diagram of a preparation process of a QLED device according to this embodiment. The preparation process of the QLED device includes the following.

(1) Preparation of a Front Film Layer 1000

A hole injection layer 400 is obtained by spin-coating Poly(3,4-ethylenedioxythiophene) (PEDOT) (3000 rpm, 30 s) on a back plate (including a substrate 100 on which a first ITO layer is deposited, an Ag layer 200, and a second ITO layer 300, wherein a combination of the second ITO layer 300 and the Ag layer 200 may be used as an anode, the anode is used as a reflective electrode to reflect light emitted from a light-emitting layer, and the second ITO layer 300 may play a protective role, such as preventing Ag penetration) and annealing at 230 degrees for 5 minutes. A hole transport layer 500 is obtained by spin-coating a chlorobenzene solution of 1,2,4,5-Tetrakis (trifluoromethyl) benzene (TFB) (3000 rpm, 30 s) and annealing at 150 degrees for 30 minutes. Then, a quantum dot layer 600 is obtained by spin-coating an octane solution of a CdSe/ZnS quantum dot layer (10 mg/ml, 2500 rpm, 30 s) and annealing at 120 degrees for 10 minutes. The preparation of the front film layer (including the substrate 100 on which the first ITO layer is deposited, the Ag layer 200, the second ITO layer 300, the hole injection layer 400, the hole transport layer 500, and the quantum dot layer 600) is completed.

(2) In-Situ Synthesis of a Zinc Oxide Nanorod

1) Preparation of a zinc oxide sol: 60 ml of absolute ethanol is added into a three-mouth round-bottomed flask equipped with a stirrer, 1.35 g of zinc acetate dihydrate is added under a stirring condition, and stirring is continued to dissolve it and a temperature is raised to 60 degrees. 0.75 g of sodium hydroxide is dissolved in 65 ml of absolute ethanol, and a sodium hydroxide ethanol solution is added dropwise into a violently stirred zinc acetate alcohol solution, and a nano ZnO sol is finally obtained by stirring for 2 hours after the dropping is completed.

2) Deposition of zinc oxide seed crystal 1 on the quantum dot layer 600: the quantum dot layer 600 is immersed into the ZnO sol prepared in the step 1), taken out after 10 minutes, pre-dried at 80 degrees for 5 minutes, and then baken at 150 degrees for 3 minutes to achieve deposition of a seed crystal layer on the quantum dot layer 600.

3) Growth control of zinc oxide nanorod: a growth solution of the zinc oxide nanorod is obtained by pouring 2.5 mmol/L of zinc nitrate and an N, N-dimethylformamide/ethanol mixed color solution of hexamethylenetetramine (100 ml in total, with a volume ratio is 1:1) into a beaker and continuing to add 0.2 g of polyethylene glycol 2000 (PEG 2000), and an array of a zinc oxide nanorod 2 is obtained by immersing a film layer with a zinc oxide seed crystal obtained in the step 2) in the growth solution, reacting at 60 degrees for two hours, taking out the film layer after the reaction, rinsing it repeatedly with ethanol, and baking at 60 degrees for 30 minutes.

4) Ion exchange: 0.5 mol/L (i.e., 20 mg/ml) of a magnesium oxide aqueous solution is prepared, 500 μl of the solution is dropwise added on a film layer of the array of the zinc oxide nanorod prepared in the step 3), standing for 10 minutes to wait for completion of ion exchange; after the completion, the film layer is washed with water and ethanol in turn, annealed and baked at 120 degrees for 20 minutes after washing, and preparation of a binary zinc oxide-magnesium oxide nanorod array is completed. One end of the nanorod close to the quantum dot layer 600 is a zinc oxide 2′ with a larger refractive index (the refractive index is 2.0), and the other end of the nanorod away from the quantum dot layer 600 is a magnesium oxide 3 with a smaller refractive index (the refractive index is 1.7), and the binary zinc oxide-magnesium oxide nanorod array exists in an erected state on the quantum dot layer 600 to form an electron transport layer 700.

(3) Preparation of the Device

On a basis of the above steps, silver electrode is evaporated to 10 nm as a cathode 800, and the preparation of the device is completed after encapsulation.

### EMBODIMENT TWO

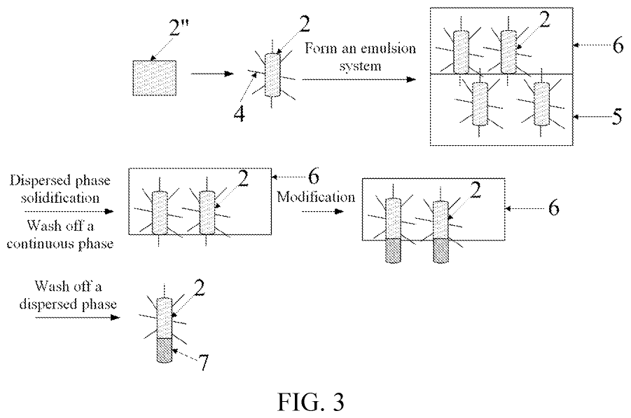

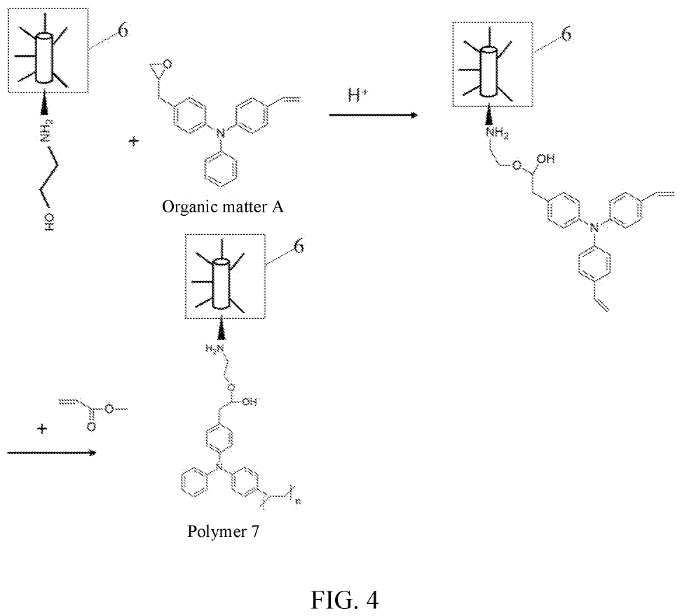

As shown in FIGS. 3 and 4, FIG. 3 is a schematic diagram of a preparation process of a QLED device according to this embodiment, and FIG. 4 is a schematic diagram of a chemical reaction of asymmetric modification for a nanorod in this embodiment.

(1) Synthesis of an Inorganic-Organic Nanorod

1) Preparation of a zinc oxide nanorod 2: taking 1.63 g (0.02 mol) of zinc oxide powder 2″ and dissolving it in 50 ml of water to form a solution with a concentration of 5 mol/L, then a concentration of zinc ions in the solution is 0.4 mol/L; taking a certain amount of the mixed solution, adding a HCl aqueous solution to adjust an alkalinity of the solution, stirring for 15 minutes after adding a certain amount of polyethylene glycol 2000 (PEG 2000), and transferring the mixed solution to a hydrothermal reaction kettle with a capacity of 100 ml; after reaction at 90 degrees for one hour, washing a sample with deionized water for three times, then dissolving it in ethanol to form a solution, adding 0.1 mol of ethanolamine as a ligand stabilizer, centrifuging after precipitating with ethyl acetate, and dried at 90 degrees after discarding a supernatant, to obtain the zinc oxide nanorod 2 with an ethanolamine ligand 4.

2) Preparation of an organic film layer at one end of the nanorod: emulsifying two mutually incompatible phases to form an emulsion by using the zinc oxide nanorod prepared in the step 1) as an emulsifier, wherein the two mutually incompatible phases are a continuous phase 5 and a dispersed phase 6 which may be converted into a solidified state, that are mutually incompatible, the continuous phase 5 is selected from any one of water, polyethylene glycol, N, N-dimethylformamide, dimethyl sulfoxide, and cyclohexane, the dispersed phase 6 is selected from any one of paraffin, normal alkane containing 17 to 60 carbon atoms, water, and polyethylene glycol, in this embodiment, the continuous phase 5 is selected as water, the dispersed phase 6 is selected as paraffin, a mass ratio of the continuous phase 5 to the dispersed phase 6 is 1:10 (in another embodiment, a mass fraction ratio of the continuous phase to the dispersed phase in an overall system composed of continuous phases and dispersed phases may be 10:1 to 1:10), and a mass of the zinc oxide nanorod 2 is 1 wt % (in another embodiment, it may be 1 wt % to 10 wt %) of a mass of the dispersed phase 6; sonicating an emulsification system at 60 degrees for 10 minutes in 100 W of ultrasound, cooling after completion until the dispersed phase 6 is transformed into a solidified state, using an interface protection effect of droplets of the dispersed phase in the solidified state, washing with water for more than three times to remove the continuous phase 5 to achieve a purpose of completely removing the continuous phase 5, and wrapping the retained dispersed phase around one end of the zinc oxide nanorod 2 as a wrapping material phase; stirring 0.05 mol of the zinc oxide nanorod with an exposed alcohol hydroxyl group at an upper end and an organic matter A containing an epoxy group (a structural formula is shown in FIG. 4) in a mixed solution of ethanol and toluene (a volume ratio is 1:1), adding a small amount of acetic acid to catalyze, reacting at 70 degrees for one hour, adding methyl methacrylate to continue reacting for one hour to form a structure of the nanorod with one end covered by a polymer 7 (a structural formula is shown in FIG. 4); placing the modified nanorod in n-hexane, a good solvent of the dispersed phase, for stirring to completely dissolve the paraffin, then obtaining a structure of the zinc oxide nanorod 2 with one end covered by the polymer through centrifugation, washing with n-hexane, and drying.

(2) Preparation of the Device

Spin-coating PEDOT (3000 rpm, 30 s) on a backplane (including a substrate 100 on which a first ITO layer is deposited, an Ag layer 200, and a second ITO layer 300, wherein a combination of the second ITO layer 300 and the Ag layer 200 may be used as an anode, the anode is used as a reflection electrode to reflect light emitted from a light-emitting layer, and the second ITO layer 300 may play a protective role, such as preventing Ag penetration), and annealing at 230 degrees for 5 minutes to obtain a hole injection layer 400; spin-coating a chlorobenzene solution of TFB (3000 rpm, 30 s) and annealing at 150 degrees for 30 minutes to obtain a hole transport layer 500; then spin-coating an octane solution of CdSe/ZnS (10 mg/ml, 2500 rpm, 30 s) to obtain a quantum dot layer 600; then, performing ligand exchange on quantum dots by using hydrophilic ligand 1-hydroxyhexanethiol, modifying a surface of the quantum dots to be super-hydrophilic, and annealing at 120 degrees for 10 minutes to complete preparation of a front film layer; then, placing an ethanol solution (5 mg/ml) of an inorganic-organic binary nanorod on the quantum dot layer for about 3 minutes, baking at 80 degrees after completion to remove a solvent to form a nanorod film layer, then forming an Ag thin film with a thickness of 10 nm through evaporation, and completing the preparation of the device after encapsulation.

Although the embodiments disclosed in the present disclosure are as above, the described contents are only embodiments used for convenience of understanding the present disclosure and are not intended to limit the present disclosure. Any person skilled in the art of the present disclosure may make any modification and change in forms and details of implementation without departing from the spirit and scope disclosed in the present disclosure. However, the scope of patent protection of the present disclosure is still subject to the scope defined in the appended claims.

1. An electron transport layer material, wherein the electron transport layer material is a nanocomposite material formed of a plurality of carrier transport materials with different refractive indexes, and the refractive indexes of the plurality of carrier transport materials increase or decrease along one direction, and refractive indexes of two adjacent carrier transport materials differ by more than 0.2.

2. The electron transport layer material according to claim 1, wherein the electron transport layer material is an inorganic-inorganic nanocomposite material formed of a plurality of inorganic electron transport materials, or an inorganic-organic nanocomposite material formed of an inorganic electron transport material and an organic carrier transport material.

3. The electron transport layer material according to claim 2, wherein the inorganic electron transport material is formed of a non-metal element and a metal element, the non-metal element is selected from Group VIA or Group VIIA, and the metal element is selected from Group IIA, Group IIIA, Group IIB, Group IIIB, or Group IVB.

4. The electron transport layer material according to claim 2, wherein the inorganic electron transport material is selected from any one or more of aluminum oxide, barium fluoride, titanium dioxide, zinc sulfide, zirconium oxide, zinc selenide, magnesium oxide, zinc oxide, yttrium oxide, and aluminum fluoride.

5. The electron transport layer material according to claim 2, wherein the organic carrier transport material contains any one or more of triphenylamine unit, carbazole unit, fluorene unit, pyridine unit, and biphenyl unit.

6. The electron transport layer material according to claim 2, wherein the electron transport layer material is an inorganic-inorganic nanocomposite material formed of a first inorganic electron transport material and a second inorganic electron transport material, a refractive index of the first inorganic electron transport material is larger than a refractive index of the second inorganic electron transport material, and a size ratio of the first inorganic electron transport material to the second inorganic electron transport material in a changing direction of the refractive indexes is 4:1 to 1:4.

7. The electron transport layer material according to claim 2, wherein the electron transport layer material is an inorganic-organic nanocomposite material formed of a third inorganic electron transport material and an organic carrier transport material, and a size ratio of the third inorganic electron transport material to the organic carrier transport material in a changing direction of the refractive indexes is more than or equal to 10:1.

8. The electron transport layer material according to claim 1, wherein the nanocomposite material is a nanorod. and a changing direction of the refractive indexes of the plurality of carrier transport materials is a length direction of the nanorod.

9. A method for preparing the electron transport layer material according to claim 1, wherein the electron transport layer material is an inorganic-inorganic nanocomposite material formed of a plurality of inorganic electron transport materials, and the method comprises:
(1) providing a first inorganic electron transport material and a second inorganic electron transport material having different refractive indexes, wherein a refractive index of the first inorganic electron transport material is greater than a refractive index of the second inorganic electron transport material by more than 0.2;
(2) depositing a seed crystal of the first inorganic electron transport material on a base material, and growing a nanomaterial of the first inorganic electron transport material on the seed crystal by using an in-situ growth method;
(3) contacting a solution of the second inorganic electron transport material with one end of the nanomaterial of the first inorganic electron transport material obtained in the step (2) and performing ion exchange to obtain an inorganic-inorganic nanocomposite material formed of the first inorganic electron transport material and the second inorganic electron transport material, wherein the inorganic-inorganic nanocomposite material is the electron transport layer material.

10. The method according to claim 9, wherein time of the ion exchange in the step (3) is 30 s to 3600 s and a concentration of the solution of the second inorganic electron transport material is 5 mg/ml to 50 mg/ml.

11. A method for preparing the electron transport layer material according to claim 1, wherein the electron transport layer material is an inorganic-organic nanocomposite material formed of an inorganic electron transport material and an organic carrier transport material, and the method comprises:
(1) providing an inorganic electron transport material;
(2) synthesizing a nanomaterial of the inorganic electron transport material containing an organic ligand;
(3) wrapping asymmetrically the nanomaterial of the inorganic electron transport material obtained in the step (2) with a wrapping material to expose one end of the nanomaterial of the inorganic electron transport material;
(4) performing a grafting reaction between the organic ligand at the exposed end of the nanomaterial of the inorganic electron transport material obtained in the step (3) and an organic grafting material, thereby introducing the organic carrier transport material into the exposed end of the nanomaterial of the inorganic electron transport material, and removing the wrapping material to obtain an inorganic-organic nanocomposite material, wherein the inorganic-organic nanocomposite material is the electron transport layer material.

12. The method according to claim 11, wherein a method used for synthesizing the nanomaterial of the inorganic electron transport material containing the organic ligand in the step (2) is a hydrothermal method or an in-situ growth method.

13. An electroluminescent device, comprising an anode, a cathode, a light-emitting layer disposed between the anode and the cathode, and an electron transport layer disposed between the light-emitting layer and the cathode, wherein the electron transport layer comprises the electron transport layer material according to claim 1.

14. The electroluminescent device according to claim 13, wherein the refractive indexes of the plurality of carrier transport materials in the nanocomposite material vary from high to low along a direction away from the light-emitting layer;
when the nanocomposite material is a nanorod, a length direction of the nanorod is approximately perpendicular to a plane where the light-emitting layer is located.

15. The electroluminescent device according to claim 13, wherein the electron transport layer material is an inorganic-inorganic nanocomposite material formed of a first inorganic electron transport material and a second inorganic electron transport material, a refractive index of the first inorganic electron transport material is greater than a refractive index of the second inorganic electron transport material, and the first inorganic electron transport material is closer to the light-emitting layer than the second inorganic electron transport material;
when LUMO (Lowest Unoccupied Molecular Orbital) energy levels of the first inorganic electron transport material and a material of the light-emitting layer are matched with each other, a size ratio of the first inorganic electron transport material to the second inorganic electron transport material in a changing direction of the refractive indexes is 4:1; and when LUMO energy levels of the second inorganic electron transport material and the material of the light-emitting layer are matched with each other, the size ratio of the first inorganic electron transport material to the second inorganic electron transport material in the changing direction of the refractive indexes is 1:4.

16. A method for preparing the electroluminescent device according to claim 13, wherein an electron transport layer material of an electron transport layer of the electroluminescent device is an inorganic-inorganic nanocomposite material formed of a plurality of inorganic electron transport materials, the method comprises: preparing an anode on a substrate; preparing a light-emitting layer on a side of the anode away from the substrate; and preparing the electron transport layer on a side of the light-emitting layer away from the anode; and a preparation process of the electron transport layer comprises:
(1) providing a first inorganic electron transport material and a second inorganic electron transport material having different refractive indexes, wherein a refractive index of the first inorganic electron transport material is greater than a refractive index of the second inorganic electron transport material by more than 0.2;
(2) depositing a seed crystal of the first inorganic electron transport material on the light-emitting layer, and growing a nanomaterial of the first inorganic electron transport material on the seed crystal by using an in-situ growth method; and
(3) contacting a solution of the second inorganic electron transport material with one end of the nanomaterial of the first inorganic electron transport material obtained in the step (2) and performing ion exchange to obtain an inorganic-inorganic nanocomposite material formed of the first inorganic electron transport material and the second inorganic electron transport material, wherein a plurality of the inorganic-inorganic nanocomposite materials form the electron transport layer on the light-emitting layer.

17. A method for preparing the electroluminescent device according to claim 13, wherein an electron transport layer material of an electron transport layer of the electroluminescent device is an inorganic-organic nanocomposite material formed of an inorganic electron transport material and an organic carrier transport material, the method comprises: preparing an anode on a substrate; preparing a light-emitting layer on a side of the anode away from the substrate; and preparing the electron transport layer on a side of the light-emitting layer away from the anode; and a preparation process of the electron transport layer comprises:
(1) providing an inorganic electron transport material;
(2) synthesizing a nanomaterial of the inorganic electron transport material containing an organic ligand;
(3) wrapping asymmetrically the nanomaterial of the inorganic electron transport material obtained in the step (2) with a wrapping material to expose one end of the nanomaterial of the inorganic electron transport material;
(4) performing a grafting reaction between the organic ligand at the exposed end of the nanomaterial of the inorganic electron transport material obtained in the step (3) with an organic grafting material, thereby introducing an organic carrier transport material into the exposed end of the nanomaterial of the inorganic electron transport material, and removing the wrapping material to obtain an inorganic-organic nanocomposite material; and
(5) dissolving the inorganic-organic nanocomposite material prepared in the step (4) in a solvent, placing it over the light-emitting layer of the electroluminescent device, and forming the electron transport layer on the light-emitting layer under a baking condition;
wherein hydrophilicity and hydrophobicity of one end of the electron transport layer material close to the light-emitting layer are the same as hydrophilicity and hydrophobicity of the light-emitting layer, hydrophilicity and hydrophobicity of one end of the electron transport layer material away from the light-emitting layer is opposite to the hydrophilicity and the hydrophobicity of the light-emitting layer, and repulsion of hydrophilicity and hydrophobicity enables the electron transport layer material to be erect to achieve a vertical arrangement with respect to the light-emitting layer.

18. A display apparatus, comprising the electroluminescent device according to claim 13.

19. The electron transport layer material according to claim 3, wherein the inorganic electron transport material is selected from any one or more of aluminum oxide, barium fluoride, titanium dioxide, zinc sulfide, zirconium oxide, zinc selenide, magnesium oxide, zinc oxide, yttrium oxide, and aluminum fluoride.

20. The electron transport layer material according to claim 3, wherein the electron transport layer material is an inorganic-inorganic nanocomposite material formed of a first inorganic electron transport material and a second inorganic electron transport material, a refractive index of the first inorganic electron transport material is larger than a refractive index of the second inorganic electron transport material, and a size ratio of the first inorganic electron transport material to the second inorganic electron transport material in a changing direction of the refractive indexes is 4:1 to 1:4.
